(19) United States
(12) Patent Application Publication
(10) Pub. No.: US 2024/0421845 A1
(43) Pub. Date: Dec. 19, 2024

(54) RADIO FREQUENCY MODULE AND COMMUNICATION APPARATUS

(71) Applicant: Murata Manufacturing Co., Ltd., Kyoto (JP)

(72) Inventors: Shogo YANASE, Kyoto (JP); Nanami YUMURA, Kyoto (JP); Masaki TADA, Kyoto (JP); Yuusuke KISHI, Kyoto (JP); Ryoya SHIOMI, Kyoto (JP); Takanori UEJIMA, Kyoto (JP); Naru MORITO, Kyoto (JP); Masaki KIMURA, Kyoto (JP); Hiroyuki NAGAMORI, Kyoto (JP); Mizuki KINOSHITA, Kyoto (JP); Minoru IWANAGA, Kyoto (JP); Takuma KUROYANAGI, Kyoto (JP)

(21) Appl. No.: 18/740,692

(22) Filed: Jun. 12, 2024

(30) Foreign Application Priority Data
Jun. 16, 2023 (JP) 2023-099369
Nov. 29, 2023 (JP) 2023-201325

(51) Int. Cl. H04B 1/40; H01Q 1/22; H03H 9/64; H03H 9/72

(52) U.S. Cl. CPC H04B 1/40; H03H 9/6423; H03H 9/72; H01Q 1/2283

(57) ABSTRACT

A radio frequency module includes a substrate having a mounting surface, components for transmission and a component for transmission and reception that are disposed on the mounting surface, acoustic wave filters disposed between each of the components for transmission and the component for transmission and reception, and shield electrodes each formed on a corresponding one of side surfaces of the acoustic wave filters.

### CROSS REFERENCE TO RELATED APPLICATION

This application claims priority from Japanese Patent Application No. 2023-099369 filed on Jun. 16, 2023 and Japanese Patent Application No. 2023-201325 filed on Nov. 29, 2023. The contents of these applications are incorporated herein by reference in their entireties.

### BACKGROUND OF THE DISCLOSURE

### 1. Field of the Disclosure

The present disclosure relates to a radio frequency module and a communication apparatus.

### 2. Description of the Related Art

U.S. Patent Application Publication No. 2018/0098418 (Patent Document 1) describes a radio frequency module in which a plurality of components are mounted on a substrate. In the radio frequency module, a shielding member is disposed between components to reduce mutual signal interference between the components. At least one end of the shielding member is connected to a ground electrode of the substrate, and thereby the shielding member functions as a shield.

### BRIEF SUMMARY OF THE DISCLOSURE

In recent years, as a communication apparatus equipped with a radio frequency module is downsized, the radio frequency module is also required to be downsized. This leads to reduction in space to dispose members solely for shielding as described in Patent Document 1 and thus leads to a concern of isolation characteristic deterioration in the radio frequency module.

The present disclosure has been made to address the issue as described above, and it is a possible benefit thereof to ensure isolation between components in a radio frequency module and also to enable the radio frequency module to be downsized.

A radio frequency module according to the present disclosure includes: a substrate having a mounting surface; a first component and a second component that are disposed on the mounting surface; a first acoustic wave filter disposed between the first component and the second component on the mounting surface; and a first shield electrode formed on at least one side surface of the first acoustic wave filter. The first shield electrode has a portion extending in a direction intersecting with a virtual line connecting the first component and the second component.

According to the present disclosure, the first acoustic wave filter is disposed between the first component and the second component, and the first shield electrode is formed on the side surface of the first acoustic wave filter. Even though a member solely for shielding is not disposed, the first shield electrode formed on the side surface of the first acoustic wave filter enables reduction in mutual signal interference between the first component and the second component. As the result, it is possible to ensure isolation between components in the radio frequency module and also to downsize the radio frequency module.

### BRIEF DESCRIPTION OF THE SEVERAL VIEWS OF THE DRAWINGS

FIG. 1 is a view schematically illustrating an example circuit configuration of a radio frequency module;

FIG. 2 is a plan view (Case 1) schematically illustrating an example internal structure of the radio frequency module;

FIG. 3 is a plan view (Case 2) schematically illustrating an example internal structure of a radio frequency module;

FIG. 4 is a plan view (Case 3) schematically illustrating an example internal structure of a radio frequency module;

FIG. 5 is a cross-sectional view schematically illustrating an example internal structure of a radio frequency module;

FIG. 6 is a plan view (Case 1) illustrating a lower surface of an acoustic wave filter;

FIG. 7 is a plan view (Case 2) illustrating a lower surface of an acoustic wave filter;

FIG. 8 is a plan view (Case 3) illustrating a lower surface of an acoustic wave filter;

FIG. 9 is a plan view (Case 4) schematically illustrating an example internal structure of a radio frequency module;

FIG. 10 is a cross-sectional view taken along the X-X line in FIG. 9;

FIG. 11 is a plan view (Case 5) schematically illustrating an example internal structure of a radio frequency module;

FIG. 12 is a plan view (Case 6) schematically illustrating an example internal structure of a radio frequency module;

FIG. 13 is a plan view (Case 7) schematically illustrating an example internal structure of a radio frequency module;

FIG. 14 is a plan view (Case 8) schematically illustrating an example internal structure of a radio frequency module;

FIG. 15 is a plan view (Case 9) schematically illustrating an example internal structure of a radio frequency module;

FIG. 16 is a plan view (Case 1) schematically illustrating example stacked structure patterns of acoustic wave filters;

FIG. 17 is a plan view (Case 2) schematically illustrating example stacked structure patterns of acoustic wave filters; and

FIG. 18 is a plan view schematically illustrating example electrode patterns of a lower surface (mounting surface) of each of acoustic wave filters.

### DETAILED DESCRIPTION OF THE DISCLOSURE

Hereinafter, an embodiment of the present disclosure will be described in detail with reference to the drawings. The same components or corresponding components in the drawings are denoted by the same reference numerals, and description thereof is not repeated.

### Circuit Configuration of Radio Frequency Module

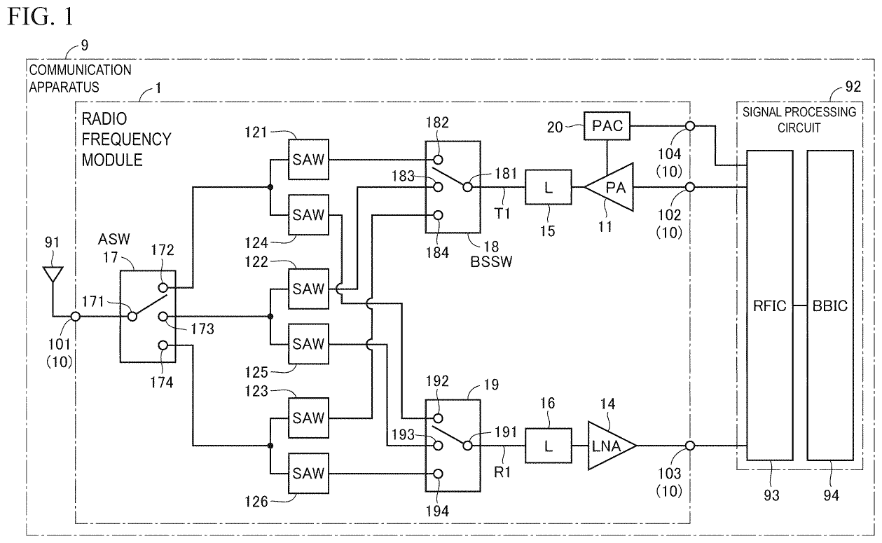

FIG. 1 is a view schematically illustrating an example circuit configuration of a radio frequency module 1 according to this embodiment.

The radio frequency module 1 is used for, for example, a communication apparatus 9. The communication apparatus 9 is a mobile phone such as a smartphone. The communication apparatus 9 is not limited to the form of a mobile phone and may be a wearable terminal such as a smart watch. The radio frequency module 1 is a module conformable to, for example, a fourth generation mobile communication (4G) standard or a fifth generation mobile communication (5G) standard.

The communication apparatus 9 performs communication in a plurality of communication bands. In more detail, the communication apparatus 9 transmits transmission signals in the plurality of communication bands and receives reception signals in the plurality of communication bands.

Some of the transmission signals and the reception signals in the plurality of communication bands are frequency division duplex (FDD) signals. The transmission signals and the reception signal in the plurality of communication bands are not limited to the FDD signals and may be time division duplex (TDD) signals. FDD is a radio communication technology in which different frequency bands are assigned to transmission and reception in radio communication and then transmission and reception are performed. TDD is a radio communication technology in which the same frequency band is assigned to transmission and reception in radio communication and then transmission and reception are performed in such a manner that switching is performed between the transmission and the reception on a per time basis.

The radio frequency module 1 includes a power amplifier (PA) 11, a power amplifier controller (PAC) 20, a plurality of (in the illustrated example, three) acoustic wave filters (SAW) 121 to 123 for transmission, a plurality of (in the illustrated example, three) acoustic wave filters (SAW) 124 to 126 for reception, a low noise amplifier (LNA) 14, a matching circuit (L) 15 for transmission, a matching circuit (L) 16 for reception, an antenna switch (ASW) 17, a band select switch (BSSW) 18 for transmission, and a bundling switch 19 for reception. The radio frequency module 1 further includes a plurality of (in the illustrated example, four) external connection terminals 10.

The power amplifier 11 is an amplifier that amplifies a transmission signal. The power amplifier 11 is disposed between a signal input terminal 102 and each of the acoustic wave filters 121 to 123 on a transmission path Ti connecting an antenna terminal 101 (described later) and the signal input terminal 102. The power amplifier 11 has an input terminal (not illustrated) and an output terminal (not illustrated). The input terminal of the power amplifier 11 is connected to an external circuit (for example, a signal processing circuit 92) with the signal input terminal 102 interposed therebetween. The output terminal of the power amplifier 11 is connected to one of the acoustic wave filters 121 to 123. The output terminal of the power amplifier 11 is only required to be directly or indirectly connected to one of the acoustic wave filters 121 to 123. In the example in FIG. 1, the output terminal of the power amplifier 11 is connected to one of the acoustic wave filters 121 to 123 with the matching circuit 15 for transmission and the band select switch 18 interposed therebetween.

The power amplifier controller 20 controls output from the power amplifier 11.

The acoustic wave filters 121 to 123 for transmission are filters that allow, to pass, transmission signals in mutually different communication bands. The acoustic wave filters 121 to 123 are disposed between the power amplifier 11 and the antenna switch 17 on the transmission path Ti. Among harmonic signals amplified by the power amplifier 11, the acoustic wave filters 121 to 123 each allow, to pass, a transmission signal in a transmission band as the corresponding communication band.

The acoustic wave filters 124 to 126 for reception are filters that allow, to pass, reception signals in mutually different communication bands. The acoustic wave filters 124 to 126 for reception are disposed between the antenna switch 17 and the low noise amplifier 14 on a reception path R1 connecting the antenna terminal 101 (described later) and a signal output terminal 103. Among harmonic signals inputted from the antenna terminal 101, the acoustic wave filters 124 to 126 for reception each allow, to pass, a reception signal in a reception band as the corresponding communication band.

The low noise amplifier 14 is an amplifier that amplifies a reception signal with low noise. The low noise amplifier 14 is disposed between the signal output terminal 103 and each of the acoustic wave filters 124 to 126 for reception on the reception path R1. The low noise amplifier 14 has an input terminal (not illustrated) and an output terminal (not illustrated). The input terminal of the low noise amplifier 14 is connected to the matching circuit 16 for reception. The output terminal of the low noise amplifier 14 is connected to the external circuit (for example, the signal processing circuit 92) with the signal output terminal 103 interposed therebetween.

The matching circuit 15 for transmission is disposed between the power amplifier 11 and each of the acoustic wave filters for transmission 121 to 123 on the transmission path Ti. The matching circuit 15 for transmission includes an inductor for performing impedance matching between the power amplifier 11 and each of the acoustic wave filters 121 to 123 for transmission.

The matching circuit 16 for reception is disposed between the low noise amplifier 14 and each of the acoustic wave filters 124 to 126 for reception on the reception path R1. The matching circuit 16 for reception includes an inductor for performing impedance matching between the low noise amplifier 14 and each of the acoustic wave filters 124 to 126 for reception.

The antenna switch 17 performs switching of an acoustic wave filter to be connected to the antenna terminal 101 among the acoustic wave filters 121 to 123 for transmission. The antenna switch 17 also performs switching for connection to the antenna terminal 101 among the acoustic wave filters 124 to 126 for reception. The antenna switch 17 has a common terminal 171 and a plurality of (in the illustrated example, three) selection terminals 172 to 174. The common terminal 171 is connected to the antenna terminal 101. Among the plurality of selection terminals 172 to 174, the selection terminal 172 is connected to the acoustic wave filters 121 and 124, the selection terminal 173 is connected to the acoustic wave filters 122 and 125, and the selection terminal 174 is connected to the acoustic wave filters 123 and 126. The antenna switch 17 electrically connects the common terminal 171 and one of the plurality of selection terminals 172 to 174, for example, in accordance with a control signal from a RF signal processing circuit 93 of the signal processing circuit 92.

The band select switch 18 for transmission performs switching of an acoustic wave filter to be connected to the power amplifier 11 among the acoustic wave filters 121 to 123 for transmission. The band select switch 18 has a common terminal 181 and a plurality of (in the illustrated example, three) selection terminals 182 to 184. The common terminal 181 is connected to the power amplifier 11. Among the plurality of selection terminals 182 to 184, the selection terminal 182 is connected to the acoustic wave filter 121, the selection terminal 183 is connected to the acoustic wave filter 122, and the selection terminal 184 is connected to the acoustic wave filter 123. The band select switch 18 electrically connects the common terminal 181 and one of the plurality of selection terminals 182 to 184, for example, in accordance with a control signal from the RF signal processing circuit 93 of the signal processing circuit 92.

The bundling switch 19 for reception performs switching of an acoustic wave filter to be connected to the low noise amplifier 14 among the acoustic wave filters 124 to 126 for reception. The bundling switch 19 has a common terminal 191 and a plurality of (in the illustrated example, three) selection terminals 192 to 194. The common terminal 191 is connected to the low noise amplifier 14. Among the plurality of selection terminals 192 to 194, the selection terminal 192 is connected to the acoustic wave filter 124, the selection terminal 193 is connected to the acoustic wave filter 125, and the selection terminal 194 is connected to the acoustic wave filter 126. The bundling switch 19 electrically connects the common terminal 191 and one of the plurality of selection terminals 192 to 194, for example, in accordance with a control signal from the RF signal processing circuit 93 of the signal processing circuit 92.

The plurality of external connection terminals 10 are each a terminal for electrical connection to the external circuit (for example, and the signal processing circuit 92). The plurality of external connection terminals 10 include the antenna terminal 101, the signal input terminal 102, the signal output terminal 103, a control terminal 104, and a ground electrode (not illustrated).

The antenna terminal 101 is connected to an antenna 91. In the radio frequency module 1, the antenna terminal 101 is connected to the antenna switch 17. The antenna terminal 101 is also connected to the acoustic wave filters 121 to 123 for transmission and the acoustic wave filters 124 to 126 for reception with the antenna switch 17 interposed therebetween.

The signal input terminal 102 is a terminal for inputting a transmission signal from the external circuit (for example, the signal processing circuit 92), to the radio frequency module 1. In the radio frequency module 1, the signal input terminal 102 is connected to the power amplifier 11.

The signal output terminal 103 is a terminal for outputting a reception signal from the low noise amplifier 14, to the external circuit (for example, the signal processing circuit 92). In the radio frequency module 1, the signal output terminal 103 is connected to the low noise amplifier 14.

The control terminal 104 is a terminal for inputting a control signal from the external circuit (for example, the signal processing circuit 92), to the radio frequency module 1. In the radio frequency module 1, the control terminal 104 is connected to the power amplifier controller 20.

As described above, the radio frequency module 1 includes components for transmission (hereinafter referred to as transmission components) used for signal transmission but not used for signal reception, such as the power amplifier (PA) 11, the power amplifier controller (PAC) 20, and the band select switch (BSSW) 18, a component for reception (reception component) that is used for signal transmission but not used for signal reception, such as the low noise amplifier (LNA) 14, and a component for transmission and reception (transmission and reception component) used for both of signal transmission and reception.

### Structure of Radio Frequency Module

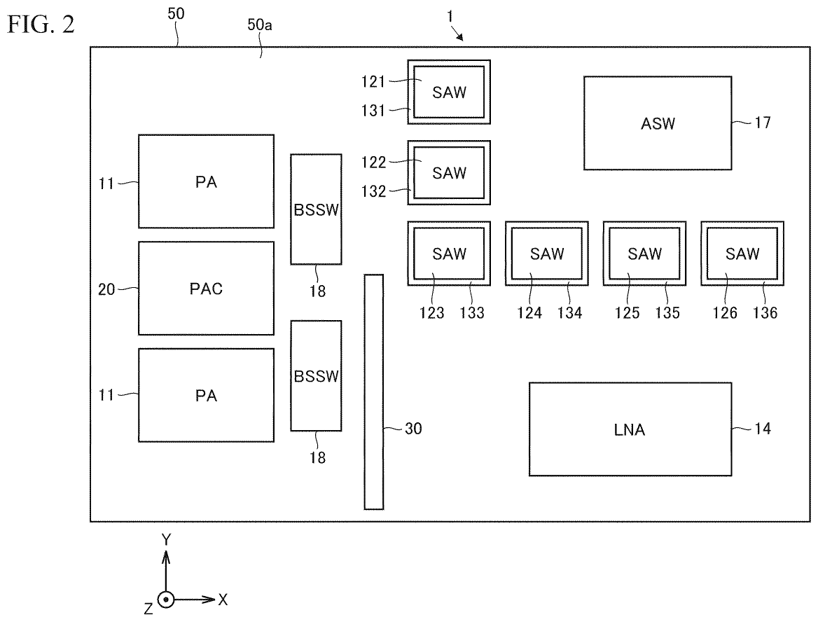

FIG. 2 is a plan view schematically illustrating an example internal structure of the radio frequency module 1. The radio frequency module 1 includes a substrate 50 of planar shape. The substrate 50 has a rectangular mounting surface 50a on which electronic components such as the power amplifier (PA) 11 described above are mounted. In the following description, a direction normal to the mounting surface 50a is referred to as a Z axis direction; a direction along the long sides of the mounting surface 50a, an X axis direction; and a direction along short sides of the mounting surface 50a, a Y axis direction. In addition, a positive direction of Z axis (in a direction from the mounting surface 50a toward the electronic components) and a negative direction of Z axis (in a direction from the electronic components toward the mounting surface 50a) in the drawings are respectively described as an upper side and a lower side on occasions.

The power amplifier (PA) 11, the power amplifier controller (PAC) 20, and the band select switch (BSSW) 18 that serve as the transmission components are arranged on a left area of the mounting surface 50a in FIG. 2. FIG. 2 illustrates an example in which the power amplifier 11 and the band select switch 18 are each divided into two.

The low noise amplifier (LNA) 14 serving as the reception component is arranged in a lower right area of the mounting surface 50a in FIG. 2. The antenna switch (ASW) 17 serving as the transmission and reception component is arranged in the upper right area of the mounting surface 50a in FIG. 2.

In the arrangement as described above, mutual signal interference may be reduced between the reception component and each transmission component, between the transmission and reception component and each transmission component, and between the reception component and the transmission and reception component. However, the radio frequency module 1 is required to be downsized in recent years, and thus it is assumed to be difficult to ensure space for arranging a member solely for shielding between these all components.

Hence, in the radio frequency module 1 according to this embodiment, the acoustic wave filters (SAW) 121 to 126 arranged side by side in an L-shaped form between the disposition area of the transmission components and the disposition area of the transmission and reception component and between the disposition area of the reception component and the disposition area of the transmission and reception component.

Further, each of shield electrodes 131 to 136 is formed on side surfaces of a corresponding one of the acoustic wave filters 121 to 126. The side surfaces of the acoustic wave filters 121 to 126 are each a surface extending in a direction intersecting with the mounting surface 50a among the respective outer surfaces of the acoustic wave filters 121 to 126. In the example illustrated in FIG. 2, the acoustic wave filters 121 to 126 are rectangular in a view in the Z axis direction and each have four side surfaces. The shield electrodes 131 to 136 are each formed on all of the four side surfaces of the corresponding acoustic wave filter.

The shield electrode 131 has a portion extending in a direction intersecting with a virtual line connecting a transmission component and a transmission and reception component. Likewise, the shield electrodes 132 and 133 also each have a portion extending in the direction intersecting with the virtual line connecting the transmission and reception component and the transmission component. Accordingly, electromagnetic noise radiated from one of the transmission and reception component and the transmission components does not reach the other and is blocked by the shield electrodes 131 to 133. This enables a characteristic in isolation between the transmission and reception component and the transmission components to be improved even though a component solely for shielding is not disposed between the transmission and reception component and the transmission components.

The shield electrode 134 also has a portion extending in a direction intersecting with a virtual line connecting the reception component and the transmission and reception component. Likewise, the shield electrodes 135 and 136 also each have a portion extending in the direction intersecting with the virtual line connecting the reception component and the transmission and reception component. Accordingly, electromagnetic noise radiated from one of the reception component and the transmission and reception component does not reach the other and is blocked by the shield electrodes 131 to 133. This enables a characteristic in isolation between the reception component and the transmission and reception component to be improved even though a component solely for shielding is not disposed between the reception component and the transmission and reception component.

As described above, in the radio frequency module 1 according to this embodiment, the acoustic wave filters 121 to 126 respectively having the shield electrodes 131 to 136 formed on the side surfaces thereof are intermittently arranged side by side between components for which isolation therebetween is desired (between the transmission and reception component and the transmission components and between the reception component and the transmission and reception component). Accordingly, even though a member solely for shielding is disposed, it is possible to reduce mutual signal interference between the transmission and reception component and the transmission components and between the reception component and the transmission and reception component. As the result, it is possible to ensure isolation between components in the radio frequency module and also to downsize the radio frequency module.

In particular, in an area including a component for handling a high power transmission signal in the transmission components and the transmission and reception component, in the radio frequency module 1 according to this embodiment, a noise signal radiated from the transmission components or the transmission and reception component at the time of transmitting a signal is blocked by the shield electrodes 131 to 136 of the acoustic wave filters 121 to 126. It is thus possible to effectively improve the isolation characteristic.

In the example illustrated in FIG. 2, there is relatively ample space in an area between each transmission component (such as the power amplifier 11) and the reception component (the low noise amplifier 14), and thus a shielding-dedicated member 30 is disposed. As described above, if there is relatively ample space, a component solely for shielding may be disposed in some area.

### Modification 1

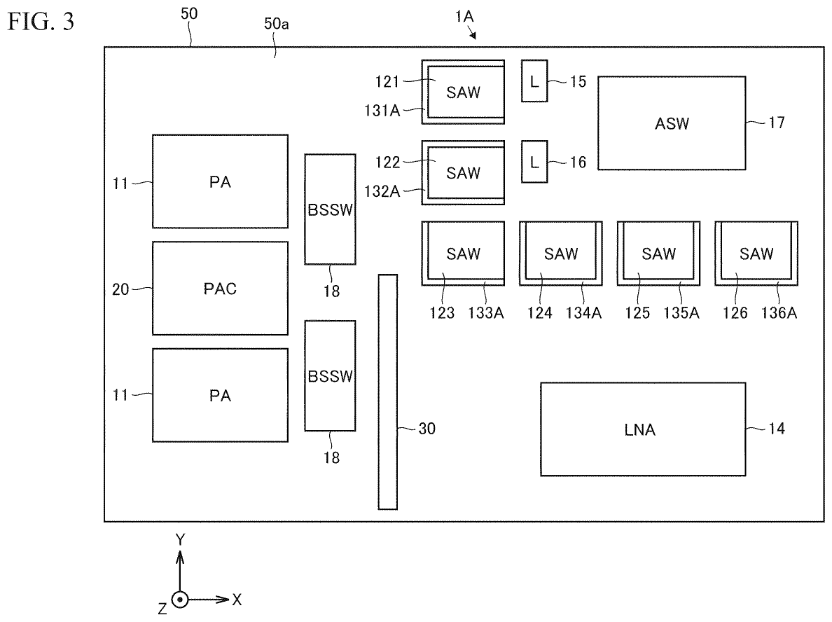

FIG. 3 is a plan view schematically illustrating an example internal structure of a radio frequency module 1A according to Modification 1. In the radio frequency module 1A according to Modification 1, the matching circuits 15 and 16 including inductors are disposed adjacent to the acoustic wave filters 121 and 122 (between the antenna switch 17 and each of the acoustic wave filters 121 and 122).

It is assumed that if a shield electrode is interposed between each of the matching circuits 15 and 16 and a corresponding one of the acoustic wave filters 121 to 126, a magnetic field generated from the inductor of each of the matching circuits 15 and 16 is distorted due to the shield electrode, and an electrical characteristic such as an inductance value of the matching circuits 15 and 16 is changed from the desired value to prevent the impedance matching.

From this viewpoint, among the side surfaces of the acoustic wave filters 121 to 126, each of shield electrodes 131A to 136A according to Modification 1 is not formed on one of the side surfaces that faces the matching circuits 15 and 16 and is formed on the remaining side surfaces not facing the matching circuits 15 and 16. This structure prevents the magnetic fields generated by the inductors included in the matching circuits 15 and 16 from being interfered by the shield electrodes 131A to 136A. As the result, it is possible to prevent the shield electrodes from causing the deterioration of the impedance matching function of the matching circuits 15 and 16. Effects that attenuation characteristics of the acoustic wave filters 121 to 126 are improved are also expected, the improvement being achieved by appropriate magnetic coupling between the inductors included in the matching circuits 15 and 16 and the acoustic wave filters 121 to 126.

### Modification 2

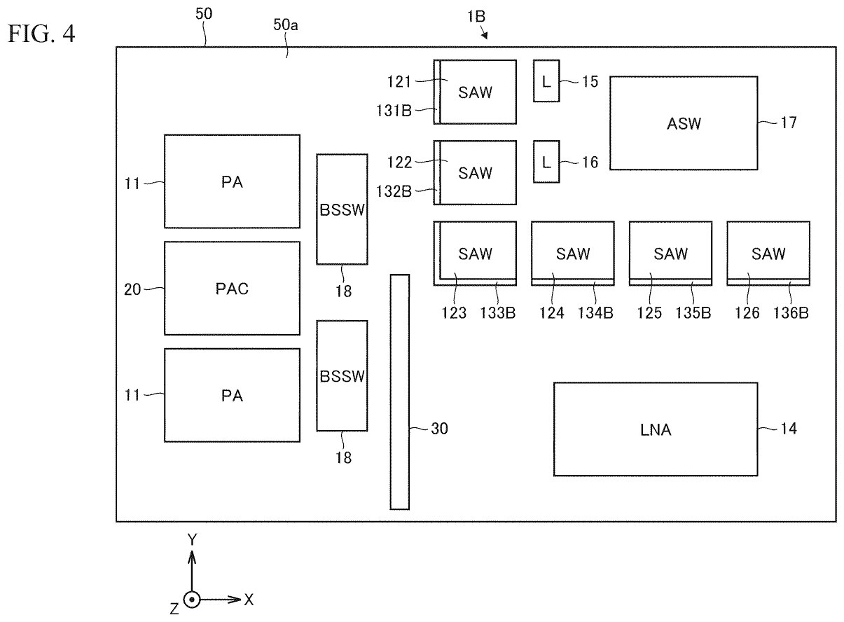

FIG. 4 is a plan view schematically illustrating an example internal structure of a radio frequency module 1B according to Modification 2. In the radio frequency module 1B according to Modification 2, the shield electrodes 131A to 136A of the radio frequency module 1A according to Modification 2 have been changed to shield electrodes 131B to 136B.

Each of the shield electrodes 131B to 136B according to Modification 2 is formed on only one or two side surfaces facing the transmission components and the reception component among the side surfaces of a corresponding one of the acoustic wave filters 121 to 126 and is not formed on the remaining side surfaces.

This enables a smaller area for forming the shield electrodes and thus leads to the cost reduction.

### Modification 3

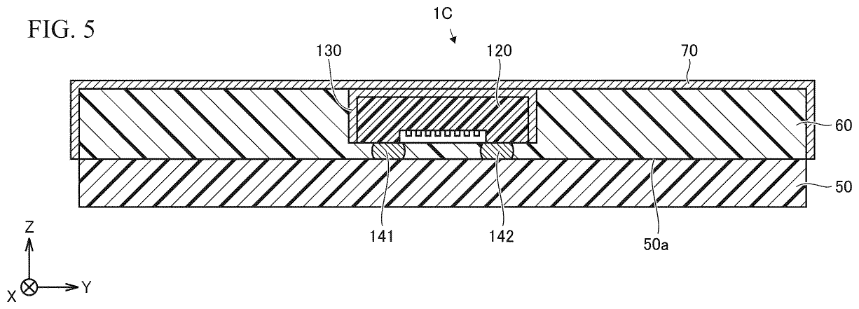

FIG. 5 is a cross-sectional view schematically illustrating an example internal structure of a radio frequency module 1C according to Modification 3. In the following description, the acoustic wave filters 121 to 126 described above are not discriminated from each other and are each described as an acoustic wave filter 120.

An upper surface portion of the radio frequency module 1C according to Modification 3 is covered with an upper surface electrode 70. The upper surface electrode 70 is grounded in a portion (not illustrated) and functions as a shield electrode of the radio frequency module 1C. The upper surface electrode 70 is also electrically conductively connected to an electrode formed on a side surface of the radio frequency module 1C, and the upper surface electrode 70 and the electrode formed on a side surface of the radio frequency module 1C enable: an unnecessary signal to be prevented from entering the radio frequency module 1C from the outside; and a magnetic field or a harmonic signal generated from an electronic component inside the radio frequency module 1C from leaking to the outside of the radio frequency module 1C.

The acoustic wave filter 120 is disposed in an area surrounded by the upper surface electrode 70 and the mounting surface 50a of the substrate 50. A lower surface of the acoustic wave filter 120 is connected to the mounting surface 50a of the substrate 50 with the solder bumps 141 and 142 interposed therebetween. The area surrounded by the upper surface electrode 70 and the mounting surface 50a of the substrate 50 is molded with resin 60.

A shield electrode 130 is formed on the side surfaces and the upper surface of the acoustic wave filter 120. The shield electrode 130 is electrically connected to the upper surface electrode 70 in a portion near the upper surface of the acoustic wave filter 120.

As described above, electrically connecting the shield electrode 130 formed on the side surfaces of the acoustic wave filter 120 to the upper surface electrode 70 of the radio frequency module 1C enables the shield electrode 130 to be grounded with the upper surface electrode 70 interposed therebetween. This enables the shield electrode 130 to appropriately function as a shield.

### Modification 4

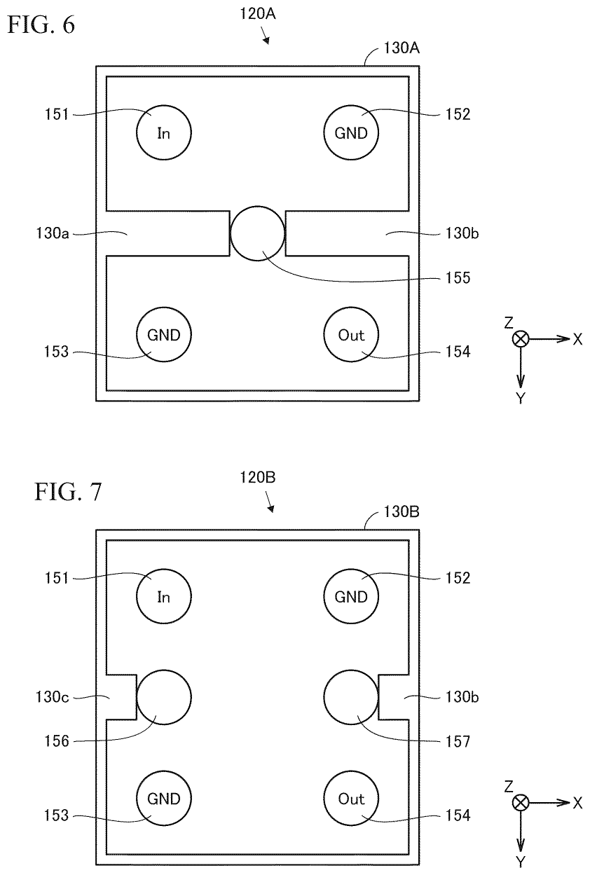

FIG. 6 is a plan view illustrating the lower surface of an acoustic wave filter 120A according to an example of Modification 4. An input electrode 151, ground electrodes 152 and 153, and an output electrode 154 to be connected to internal electric components are disposed near the four corners of the lower surface of the acoustic wave filter 120A. These terminals 151 to 154 are connected to the mounting surface 50a of the substrate 50 with solder bumps interposed therebetween.

Further, a circular ground electrode 155 not connected to any of the internal electric components is disposed near the center of the lower surface of the acoustic wave filter 120A. The ground electrode 155 is connected to a ground electrode formed on the mounting surface 50a of the substrate 50 with the solder bumps interposed therebetween.

A shield electrode 130A formed on the side surfaces of the acoustic wave filter 120A has connection portions 130a and 130b extending on the lower surface of the acoustic wave filter 120A and electrically connected to the ground electrode 155. The shield electrode 130 is thereby grounded with the ground electrode 155 on the lower surface of the acoustic wave filter 120A interposed therebetween.

In the acoustic wave filter 120 according to Modification 3 described above, the shield electrode 130 formed on the side surfaces is connected to the upper surface electrode 70 of the radio frequency module 1C near the upper surface of the acoustic wave filter 120 and is thereby grounded.

In contrast, in the acoustic wave filter 120A according to Modification 4, the shield electrode 130A formed on the side surfaces thereof is connected to the ground electrode 155 disposed on the lower surface and is thereby grounded. This enables the shield electrode 130A to be grounded even though an electrode or processing (such as vias) for grounding the shield electrode 130 is not added to the inside of the acoustic wave filter 120A or the radio frequency module 1. It is thus possible to ground the shield electrode 130A without changing an area for exclusive use in the radio frequency module 1 and without increasing manufacturing steps of the radio frequency module 1.

The ground electrode 155 for the shield electrode 130A is not connected to an electric component inside the acoustic wave filter 120A. It is thus possible to dispose the ground electrode 155 without changing the shape of a cover layer forming the lower surface of the acoustic wave filter 120A.

In consideration of a case where the ground electrodes 152 and 153 connected to electric components inside the acoustic wave filter 120A are provided with inductance components, the ground electrode 155 for the shield electrode 130A is provided separately from the ground electrodes 152 and 153. This enables the ground electrode 155 to be disposed without changing the inductance components of the ground electrodes 152 and 153 as much as possible.

The number of the ground electrode 155 for the shield electrode 130A illustrated in FIG. 6 is one, but two or more ground electrodes may be provided for the shield electrode 130A.

FIG. 7 is a plan view illustrating the lower surface of an acoustic wave filter 120B according to another example of Modification 4. In the acoustic wave filter 120B, two ground electrodes 156 and 157 for a shield electrode 130B are disposed at right and left positions. Connection portions 130c and 130d of the shield electrode 130B are respectively connected to the two ground electrodes 156 and 157. As described above, the two ground electrodes 156 and 157 for the shield electrode 130A may be disposed on the lower surface of the acoustic wave filter 120B.

Although the ground electrode 155 for the shield electrode 130A illustrated in FIG. 6 has a circular shape, the shape of a ground electrode for the shield electrode 130A is not limited to the circle.

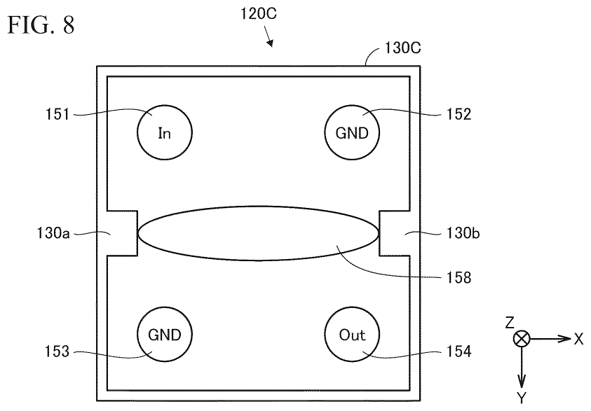

FIG. 8 is a plan view illustrating lower surface of an acoustic wave filter 120C according to another example of Modification 4. In the acoustic wave filter 120C, a ground electrode 158 for the shield electrode 130 is shaped into an ellipse with the X axis direction serving as a long axis. Connection portions 130e and 130f of a shield electrode 130C are connected to the ground electrode 158. As described above, the elliptical for the ground electrode 158 of the shield electrode 130C may be disposed on the lower surface of the acoustic wave filter 120B.

In any one of the cases, from the viewpoint of ensuring the reliability of the acoustic wave filter, the positions of the electrodes disposed on the lower surface of the acoustic wave filter may have point symmetry. In the examples illustrated in FIGS. 6 to 8 described above, the electrodes are disposed point symmetrically with respect to the center of the lower surface of the acoustic wave filter. This ensures acoustic wave filter reliability.

### Modification 5

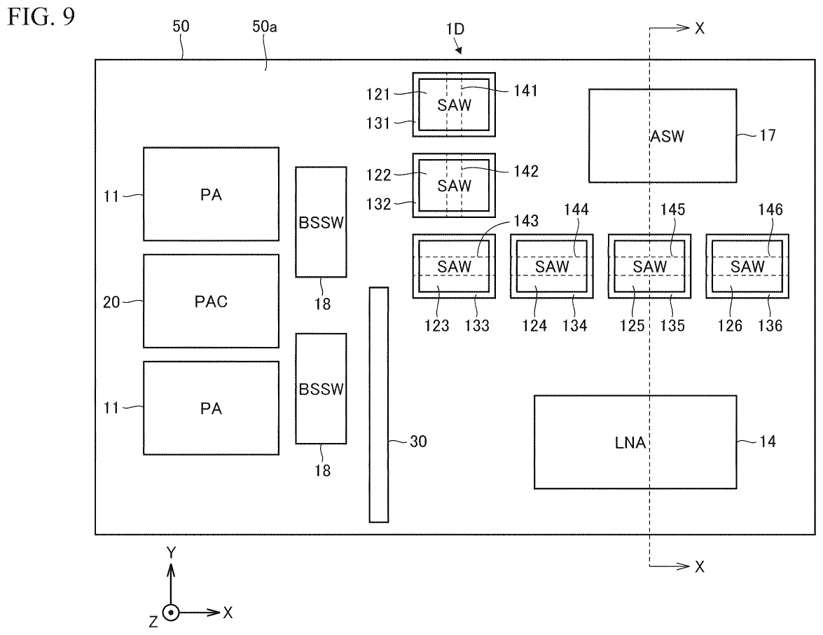

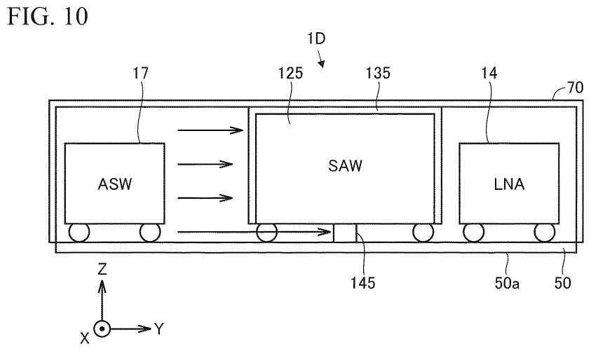

FIG. 9 is a plan view schematically illustrating an example internal structure of a radio frequency module 1D according to Modification 5. FIG. 10 is a cross-sectional view taken along the X-X line in FIG. 9.

In the radio frequency module 1D according to Modification 5, long stripe bumps (linear bumps) 141 to 146 are respectively disposed on the lower surfaces (mounting surfaces) of the acoustic wave filters 121 to 126.

The stripe bumps 141 to 146 are each disposed to isolate components for which isolation is to be ensured (between the transmission and reception component and the transmission components and between the reception component and the transmission and reception component). Specifically, the stripe bumps 141 and 142 extend in the Y axis direction intersecting with the virtual line connecting the transmission component (such as the PA 11) and the transmission and reception component (ASW 17). Stripe bumps 143 to 146 extend in the X axis direction intersecting with the virtual line connecting the reception component (LNA 14) and the transmission and reception component (ASW 17). The stripe bumps 143 to 146 in addition to the shield electrodes 131 to 136 also thereby enable mutual signal interference to be reduced between the transmission and reception component and the transmission components and between the reception component and the transmission and reception component. As illustrated in, for example, FIG. 10, electromagnetic noise radiated in a direction from the ASW 17 toward the LNA 14 is blocked not only by the shield electrode 135 disposed on the side surfaces of the acoustic wave filter 125 but also by the stripe bump 145 disposed on the lower surface of the acoustic wave filter 125. As the result, disposing the stripe bump 145 enables isolation between the ASW 17 and the LNA 14 to be enhanced.

The lower surfaces of the stripe bumps 141 to 146 are connected to the ground electrode formed on the mounting surface 50a of the substrate 50. Each of the shield electrodes 131 to 136 is connected to both ends of a corresponding one of the stripe bumps 141 to 146 on the fringe of the lower surface of a corresponding one of the acoustic wave filters 121 to 126. This enables the shield electrodes 131 to 136 to be grounded with the stripe bumps 141 to 146 interposed therebetween and thus the shielding property of the shield electrodes 131 to 136 to be enhanced.

### Modification 6

In recent years, carrier aggregation (CA) technology has been put to practical use. In the CA technology, communication speed is increased in such a manner that a channel capacity per unit time is increased by simultaneously transmitting or receiving signals in mutually different bands (frequency bands). To simultaneously transmit or receive the signals in the mutually different bands, the acoustic wave filter 120 with the shield electrode 130 formed on the side surfaces thereof may be disposed at a position intersecting with a virtual line connecting matching circuits (inductors) in mutually different bands.

For example, in a case where transmission of radio waves in mutually different bands are simultaneously performed, the acoustic wave filter 120 with the shield electrode 130 formed on the side surfaces thereof may be disposed at a position intersecting with a virtual line connecting transmission components in mutually different bands.

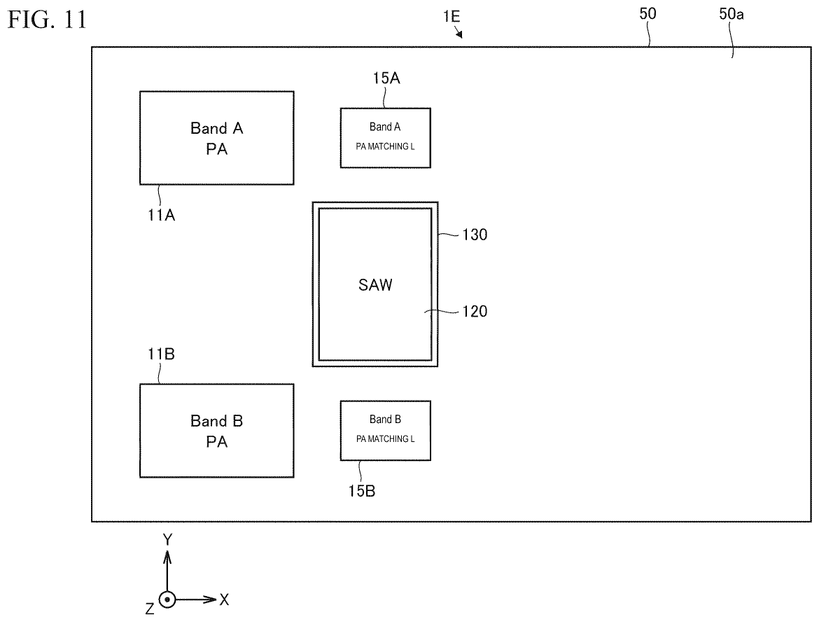

FIG. 11 is a plan view schematically illustrating an example internal structure of a radio frequency module 1E according to Modification 6. The radio frequency module 1E is configured to simultaneously transmit radio waves in mutually different Bands A and B. The radio frequency module 1E includes a power amplifier 11A for Band A radio wave transmission, an inductor 15A for output matching for the power amplifier 11A, a power amplifier 11B for Band B radio wave transmission, an inductor 15B for output matching for the power amplifier 11B, and the acoustic wave filter 120 with the shield electrode 130.

The acoustic wave filter 120 with the shield electrode 130 is disposed at a position intersecting with a virtual line connecting the inductor 15A for output matching for the power amplifier 11A and the inductor 15B for output matching for the power amplifier 11B. This enables intermodulation distortion (IMD) occurring due to interference between the radio waves in the mutually different bands to be prevented when the transmissions of the radio wave in Band A and the radio wave in Band B are simultaneously performed.

In addition, for example, in a case where transmission of the radio wave in Band A and reception of the radio wave in Band C are simultaneously performed, the acoustic wave filter 120 with the shield electrode 130 disposed on the side surfaces thereof may be disposed at a position intersecting with the virtual line connecting a component for transmitting the radio wave in Band A and a component for receiving the radio wave in Band C.

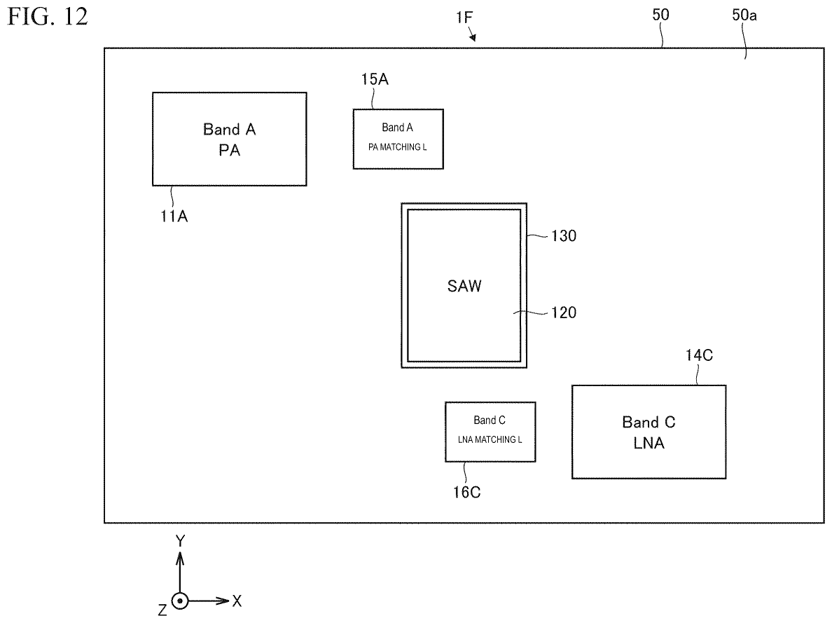

FIG. 12 is a plan view schematically illustrating an example internal structure of a radio frequency module 1F according to another example of Modification 6. The radio frequency module 1F is configured to simultaneously perform transmission of the radio wave in Band A and reception of the radio wave in Band C. The radio frequency module 1F includes the power amplifier 11A for Band A radio wave transmission, the inductor 15A for output matching for the power amplifier 11A, a low noise amplifier 14C for Band C radio wave reception, an inductor 16C for input matching for the low noise amplifier 14C, and the plurality of acoustic wave filters 120 each having the shield electrode 130.

The acoustic wave filter 120 with the shield electrode 130 is disposed at a position intersecting with a virtual line connecting the inductor 15A for output matching for the power amplifier 11A and the inductor 16C for input matching for the low noise amplifier 14C. This enables prevention of signal interference at the time of simultaneously performing the transmission of the radio wave in Band A and the reception of the radio wave in Band C.

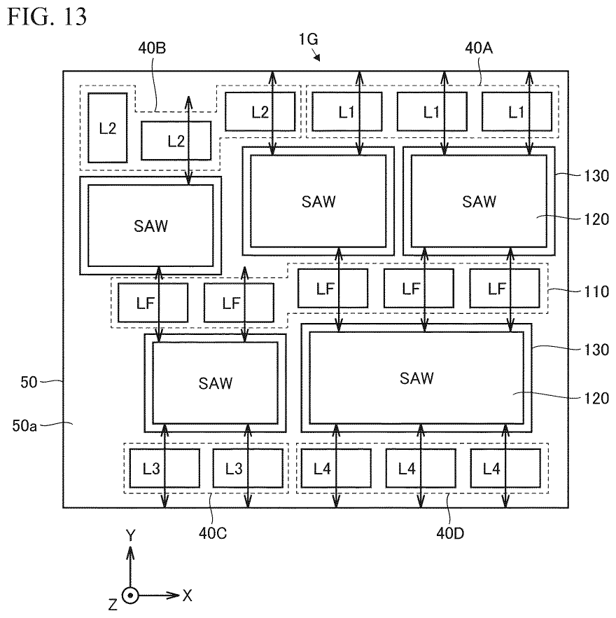

FIG. 13 is a plan view schematically illustrating an example internal structure of a radio frequency module 1G according to another example of Modification 6. The radio frequency module 1G is configured to be able to, among radio waves in mutually different four bands A, B, C, and D, simultaneously receive the radio wave in Band A and the radio wave in Band D and simultaneously receive the radio wave in Band B and the radio wave in Band C.

The radio frequency module 1G includes input matching elements 40A for low noise amplifiers for Band A radio wave reception, input matching elements 40B for low noise amplifiers for Band B radio wave reception, input matching elements 40C for low noise amplifiers for Band C radio wave reception, input matching elements 40D for low noise amplifiers for Band D radio wave reception, the plurality of acoustic wave filters 120 each having the shield electrode 130, and input matching circuit elements 110 for the acoustic wave filters 120.

In the radio frequency module 1G, the plurality of input matching circuit elements 110 for the acoustic wave filter are disposed in the X axis direction in the center of the substrate 50 in the Y axis direction, and the plurality of acoustic wave filters 120 each having the shield electrode 130 are disposed on the both sides of the input matching circuit elements 110 in such a manner that the input matching circuit elements 110 are sandwiched. Further, the input matching elements 40A and 40B on which reception is not simultaneously performed are disposed closer to the outer edge of the radio frequency module 1G in the positive direction of the Y axis than the acoustic wave filter 120, and the input matching elements 40C and 40D on which reception is not simultaneously performed are disposed closer to the outer edge in the negative direction of the Y axis than the acoustic wave filter 120.

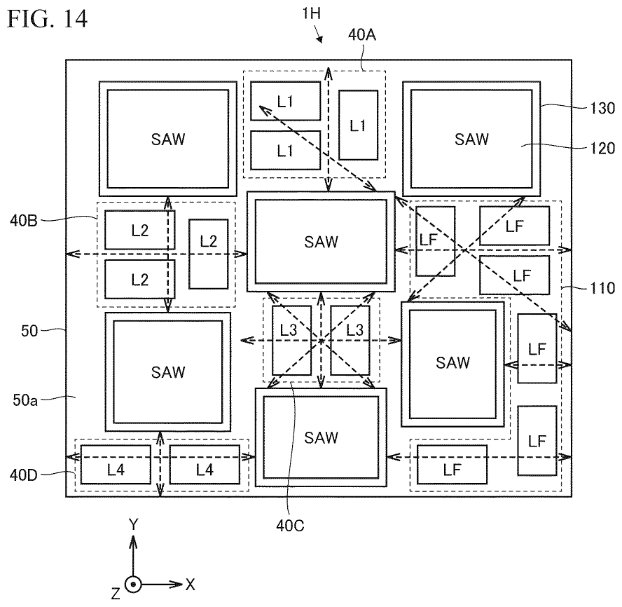

FIG. 14 is a plan view schematically illustrating an example internal structure of a radio frequency module 1H according to another example of Modification 6. Like the radio frequency module 1G described above, the radio frequency module 1H is configured to be able to, among the radio waves in mutually different four bands A, B, C, and D, simultaneously receive the radio wave in Band A and the radio wave in Band D and simultaneously receive the radio wave in Band B and the radio wave in Band C.

In the radio frequency module 1H, the input matching elements 40A to 40D for low noise amplifiers, the plurality of acoustic wave filters 120 each having the shield electrode 130, and the input matching circuit elements 110 for the acoustic wave filters are disposed in a grid-like pattern.

In each of the radio frequency modules 1G and 1H, the plurality of acoustic wave filters 120 each having the shield electrode 130 are disposed at positions each intersecting with a virtual line connecting a corresponding one of the input matching elements 40A and 40D on which the simultaneous reception is performed and at positions each intersecting with a virtual line connecting a corresponding one of the input matching elements 40B and 40C on which the simultaneous reception is performed. This enables improvement of a characteristic in isolation between a reception component in one of the bands and a reception component in the other band on which reception is simultaneously performed. As the result, it is possible to reduce reception sensitivity deterioration in one of the bands due to a signal in the other band on which the reception is simultaneously performed.

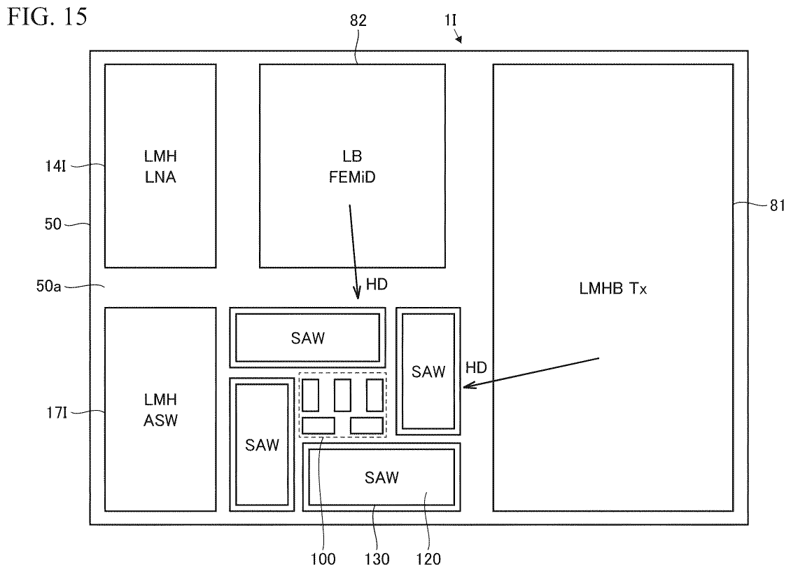

FIG. 15 is a plan view schematically illustrating an example internal structure of a radio frequency module 1I according to another example of Modification 6. The radio frequency module 1I supports any of Low, Mid, and High frequency bands. Specifically, the radio frequency module 1I includes a transmission component 81 for Low, Mid, and High bands (such as a power amplifier or an output matching element of the power amplifier), a transmission component (such as a front end module) 82 for Low band, a low noise amplifier 141 and an antenna switch 171 for Low and Mid bands, and antenna matching elements (such as inductors) 100 for Mid and High bands.

There is a concern of reception sensitivity deterioration in Mid and High bands in the following case: a harmonic (second harmonic or third harmonic) HD of a transmission signal in Low band occurring at the transmission component 81 for Low, Mid, and High bands or the transmission component 82 for Low band overlaps with Mid and High bands, and thus the harmonic HD of the transmission signal in Low band leaks to the antenna matching elements 100.

Hence, in the radio frequency module 1I, the plurality of acoustic wave filters 120 each having the shield electrode 130 are disposed to surround the antenna matching elements 100 for Mid and High bands. The harmonic HD occurring in the transmission signal in Low band at the transmission components 81 and 82 is thereby prevented from leaking to the antenna matching elements 100. As the result, it is possible to reduce the reception sensitivity deterioration in Mid and High bands.

### Modification 7

The acoustic wave filter 120 with the shield electrode 130 and a different electronic component may be disposed to be stacked with each other.

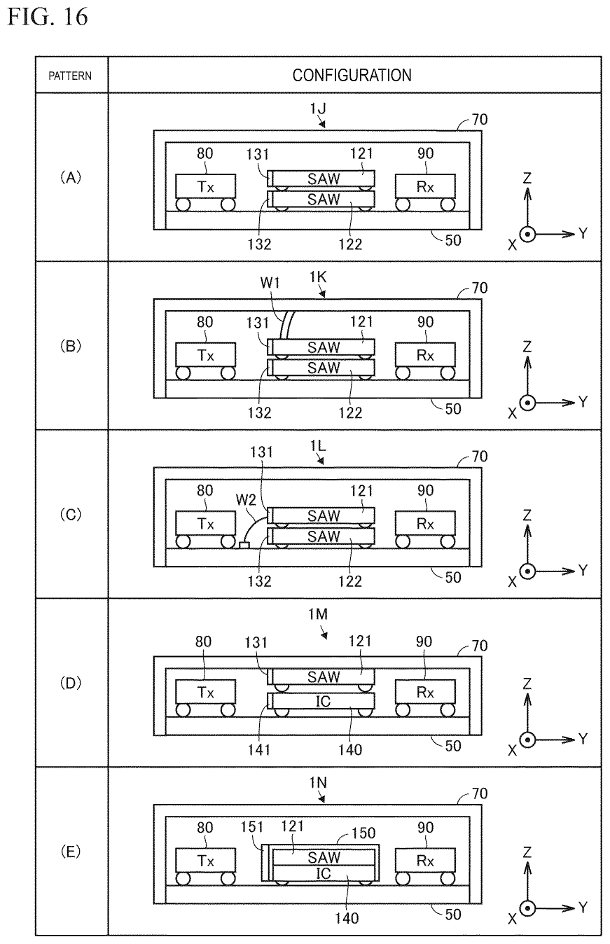

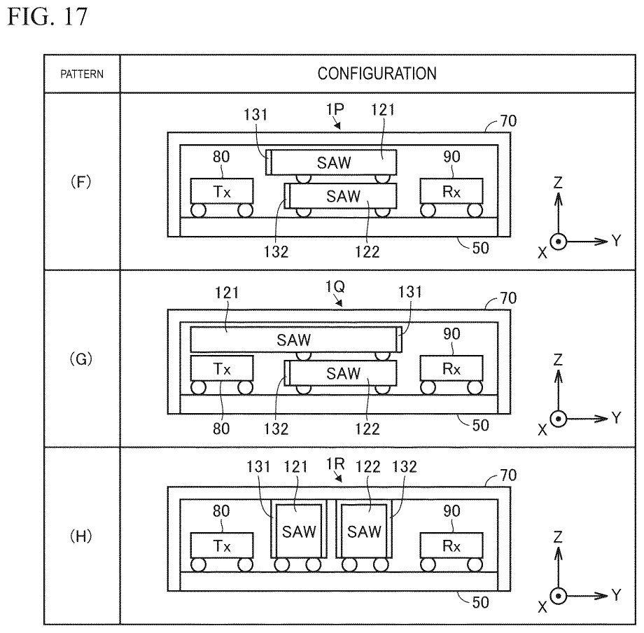

FIGS. 16 and 17 are each a plan view schematically illustrating example stacked structure patterns of the acoustic wave filters 120 according to Modification 7.

As represented in Patterns (A), (B), and (C) in FIG. 16, a structure in which the acoustic wave filter 121 is stacked on the acoustic wave filter 122 as the different component may be disposed between a transmission component 80 and a reception component 90.

In radio frequency modules 1J, 1K, and 1L respectively illustrated in Patterns (A), (B), and (C), the acoustic wave filter 121 is stacked on the acoustic wave filter 122 as the different component, and the shield electrodes 131 and 132 are each formed on a side surface, in the negative direction of the Y axis, of a corresponding one of the acoustic wave filters 121 and 122. The shield electrode 132 is electrically connected to the ground electrode of the substrate 50 with the electrode on the bottom surface of the acoustic wave filter 122 interposed therebetween.

The radio frequency modules 1J, 1K, and 1L have mutually different grounding paths of the shield electrode 131.

In the radio frequency module 1J illustrated in Pattern (A), the shield electrode 131 is electrically connected to the ground electrode of the substrate 50 with the electrode on the bottom surface of the acoustic wave filter 121, the electrode on the top surface of the acoustic wave filter 122, the shield electrode 132 on the side surface, and the electrode on the bottom surface interposed therebetween.

In the radio frequency module 1K illustrated in Pattern (B), the shield electrode 131 is connected to the upper surface electrode 70 with a wire W1, the shield electrode 131 is thus electrically connected to the ground electrode of the substrate 50 with the wire W1 and the upper surface electrode 70 interposed therebetween.

In the radio frequency module 1L illustrated in Pattern (C), the shield electrode 131 is connected to a ground electrode G1 of the substrate 50 with a wire W2 interposed therebetween.

As illustrated in Patterns (D) and (E) in FIG. 16, a structure in which the acoustic wave filter 121 is stacked on an electronic circuit 140 other than the acoustic wave filter may be disposed between the transmission component 80 and the reception component 90.

In a radio frequency module 1M illustrated in Pattern (D), the upper end of the shield electrode 131 is connected to the upper surface electrode 70, and the shield electrode 131 is electrically connected to the ground electrode of the substrate 50 with the upper surface electrode 70 interposed therebetween.

In a radio frequency module 1N illustrated in Pattern (E), the acoustic wave filter 121 and the electronic circuit 140 as a different component are integrally molded with resin 150, and a shield electrode 151 is formed on a side surface, in the negative direction of the Y axis, of the resin 150.

As illustrated in Patterns (F) and (G) in FIG. 17, in plan view of a radio frequency module in the Z axis direction, the radio frequency module may have a portion where one of the acoustic wave filter 121 and a different component on which the acoustic wave filter 121 is stacked does not overlap with the other.

In a radio frequency module 1P illustrated in Pattern (F), the acoustic wave filter 121 is stacked on the acoustic wave filter 122, and an end portion, in the negative direction of the Y axis, of the acoustic wave filter 121 on the upper side protrudes to an area between the acoustic wave filter 122 and the transmission component 80 on the lower side. The shield electrodes 131 and 132 are each formed on a side surface, in the negative direction of the Y axis, of a corresponding one of the acoustic wave filters 121 and 122.

In a radio frequency module 1Q illustrated in Pattern (G), the acoustic wave filter 121 is stacked on the acoustic wave filter 122, and an end portion, in the negative direction of the Y axis, of the acoustic wave filter 121 on the upper side protrudes to an area above the transmission component 80. The shield electrode 132 is formed on a side surface, in the negative direction of the Y axis, of the acoustic wave filter 122, but the shield electrode 131 is formed on a side surface, in the positive direction of the Y axis, of the acoustic wave filter 121.

In the radio frequency modules 1J to 1Q respectively illustrated in Patterns (A) to (G), the acoustic wave filter 121 is stacked on a different component (the acoustic wave filter 122 or the electronic circuit 140 as the different component) in the Z axis direction, and the shield electrodes 131 and 132 are respectively formed on a side surface of the acoustic wave filter 120 and a side surface of the different component. This causes the shield electrodes 131 and 132 to be arranged in the Z axis direction to ensure the height of the shield electrodes and thus enables further improvement in a characteristic in isolation between the transmission component 80 and the reception component 90. Further, disposing the acoustic wave filter 121 and the different component in a stacked manner enables the radio frequency module to be downsized.

As in a radio frequency module 1R illustrated in Pattern (H) in FIG. 17, the acoustic wave filter 121 with the shield electrode 131 and the acoustic wave filter 122 with the shield electrode 132 may be arranged side by side in the Y axis direction in an area between the transmission component 80 and the reception component 90. The configuration as described above also enables further improvement in a characteristic in isolation between the transmission component 80 and the reception component 90.

### Modification 8

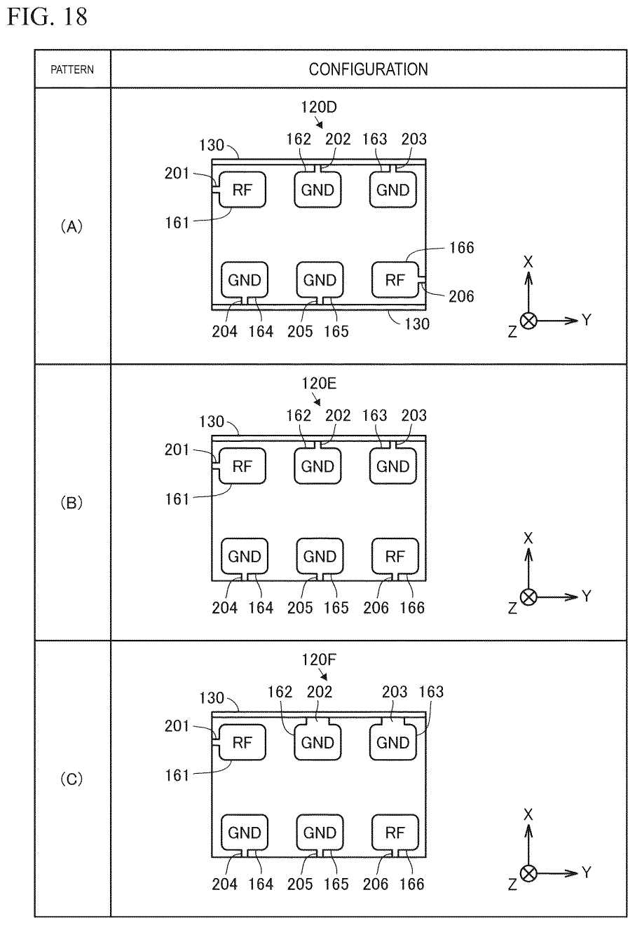

FIG. 18 is a plan view schematically illustrating example electrode patterns on the lower surface (mounting surface) of each of acoustic wave filters according to Modification 8. Typically, in a case where a land electrode on the lower surface of the acoustic wave filter is formed with electroplating, a plated electrode is formed on only an energized electrode. Accordingly, to conduct the land electrode and an external device, a wiring line for connecting the land electrode and the eternal device is required to be formed on the lower surface of the acoustic wave filter.

Signal electrodes 161 and 166 and ground electrodes 162 to 165 each of which is formed with electroplating are arranged on respective lower surfaces of acoustic wave filters 120D, 120E, and 120F respectively illustrated in Patterns (A), (B), and (C) in FIG. 18. The signal electrodes 161 and 166 are land electrodes for signal input and output that are electrically connected to a circuit inside the acoustic wave filter. The ground electrodes 162 to 165 are land electrodes for grounding that are electrically connected to the circuit inside the acoustic wave filter.

Wiring lines 201 to 206 in addition to the signal electrodes 161 and 166 and the ground electrodes 162 to 165 are formed on the lower surface of each of the acoustic wave filters 120D, 120E, and 120F. The wiring lines 201 and 206 are wiring lines for conduction between each of the signal electrodes 161 and 166 and a corresponding external device. The wiring lines 202 to 205 are wiring lines for conduction between each of the ground electrodes 162 to 165 and the outside.

In the acoustic wave filter 120D illustrated in Pattern (A), the shield electrodes 130 are respectively formed on a side surface located in the positive direction of the X axis and a side surface located in the negative direction of the X axis. An end portion of the wiring line 201 for the signal electrode 161 is exposed on a side surface that is located in the negative direction of the Y axis and on which any shield electrode 130 is not formed. Likewise, the other end of the wiring line 206 for a signal electrode 166 is exposed on a side surface that is located in the positive direction of the Y axis and on which any shield electrode 130 is not formed. End portions of the wiring lines 202 and 203 for the ground electrodes 162 and 163 are exposed on side surfaces located in the positive direction of the X axis and are connected to one of the shield electrodes 130. Likewise, end portions of the wiring lines 204 and 205 for the ground electrodes 164 and 165 are exposed on side surfaces located in the negative direction of the X axis and are connected to the other shield electrode 130.

Arranging the wiring lines 201 to 206 as in Pattern (A) enables a signal input and output to and from the signal electrodes 161 and 166 and enables each shield electrode 130 to be provided with a shielding property by grounding the shield electrode 130.

The acoustic wave filter 120E illustrated in Pattern (B) is different from the acoustic wave filter 120D illustrated in Pattern (A) in that the shield electrode 130 located in the negative direction of the X axis is removed and that the end portion of the wiring line 206 for the signal electrode 166 is exposed on the side surface located in the negative direction of the X axis.

Arranging the wiring lines 201 to 206 as in Pattern (B) also enables a signal input and output to and from the signal electrodes 161 and 166 and enables the shield electrode 130 to be provided with a shielding property by grounding the shield electrode 130.

The acoustic wave filter 120F illustrated in Pattern (C) is different from the acoustic wave filter 120E illustrated in Pattern (B) in that the width (a dimension in the Y axis direction) of each of the wiring lines 202 and 203 for the ground electrodes 162 and 163 is increased. Increasing the width of each of the wiring lines 202 and 203 for the ground electrodes 162 and 163 as described above enables the grounding property of the shield electrode 130 to be improved and thus the shielding property of the shield electrode 130 to be improved.

The embodiment and the modifications thereof disclosed at this time are to be construed as being illustrative and not restrictive in all aspects. It is intended that the scope of the disclosure be defined by the scope of claims, not by the description of the embodiment above, and include the meaning equivalent to the scope of claims and any changes made within the scope.

It is understood by those skilled in the art that the embodiment and the modifications thereof described above are specific examples of the following aspects.

### First Aspect

A radio frequency module according to the present disclosure includes a substrate having a mounting surface; a first component and a second component that are disposed on the mounting surface; a first acoustic wave filter disposed between the first component and the second component on the mounting surface; and a first shield electrode formed on at least one side surface of the first acoustic wave filter. The first shield electrode has a portion extending in a direction intersecting with a virtual line connecting the first component and the second component.

### Second Aspect

The radio frequency module according to the first aspect further includes: a second acoustic wave filter disposed between the first component and the second component on the mounting surface, the second acoustic wave filter being disposed alongside the first acoustic wave filter; and a second shield electrode formed on at least one side surface of the second acoustic wave filter. The second shield electrode has a portion extending in the direction intersecting with the virtual line connecting the first component and the second component.

### Third Aspect

The radio frequency module according to the first aspect further includes an inductor disposed adjacent to the first acoustic wave filter on the mounting surface. The inductor is electrically connected to the first acoustic wave filter. The first acoustic wave filter has a first side surface facing the inductor and a second side surface not facing the inductor. The first shield electrode is not formed on the first side surface but is formed on the second side surface.

### Fourth Aspect

In the radio frequency module according to the first aspect, the first component is a component used to transmit a signal.

### Fifth Aspect

The radio frequency module according to the first aspect further includes an upper surface electrode formed on an upper surface portion of the radio frequency module. The first shield electrode is electrically connected to the upper surface electrode.

### Sixth Aspect

In the radio frequency module according to the first aspect, the first acoustic wave filter has a lower surface connected to the mounting surface with a bump electrode interposed therebetween. A ground electrode not electrically connected to a circuit inside the first acoustic wave filter is disposed on the lower surface of the first acoustic wave filter. The first shield electrode is electrically connected to the ground electrode.

### Seventh Aspect

A communication apparatus according to the present disclosure includes: the radio frequency module according to any one of the first to sixth aspects; and an external circuit connected to the radio frequency module.

### Eighth Aspect

In the radio frequency module according to the first aspect, a long bump electrode electrically connected to a circuit inside the first acoustic wave filter is disposed on a lower surface of the first acoustic wave filter. The long bump electrode has a portion extending in a direction intersecting with the virtual line connecting the first component and the second component.

### Ninth Aspect

In the radio frequency module according to the first aspect, the first component is a component used to transmit a signal with a first frequency. The second component is a component used to transmit or receive a signal with a second frequency different from the first frequency.

### Tenth Aspect

The radio frequency module according to the first aspect further includes a third component disposed alongside the first acoustic wave filter; a second shield electrode formed on at least one side surface of the third component. The second shield electrode has a portion extending in the direction intersecting with the virtual line connecting the first component and the second component.

### Eleventh Aspect

In the radio frequency module according to the tenth aspect, the first acoustic wave filter and the third component are disposed to be stacked with each other.

### Twelfth Aspect

In the radio frequency module according to the eleventh aspect, the third component is an electronic component.

### Thirteenth Aspect

In the radio frequency module according to the eleventh aspect, in plan view of the first acoustic wave filter and the third component in a direction normal to the substrate, the radio frequency module has a portion where one of the first acoustic wave filter and the third component does not overlap with the other one of the first acoustic wave filter and the third component.

### Fourteenth Aspect

In the radio frequency module according to the first aspect, the first acoustic wave filter has a lower surface connected to the mounting surface with a bump electrode interposed therebetween. A ground electrode electrically connected to a circuit inside the first acoustic wave filter is disposed on the lower surface of the first acoustic wave filter. The first shield electrode and the ground electrode are connected with a connection wiring line for grounding interposed therebetween, the connection wiring line being exposed on the side surface of the first acoustic wave filter.

### Fifteenth Aspect

In the radio frequency module according to the fourteenth aspect, a signal electrode electrically connected to the circuit inside the first acoustic wave filter is disposed on the lower surface of the first acoustic wave filter. The signal electrode is connected to a signal connection wiring line having an end portion exposed on a side surface different from the side surface in which the first shield electrode is formed.

### Sixteenth Aspect

The communication apparatus according to the present disclosure includes the radio frequency module according to any one of the ninth to fifteenth aspects; and an external circuit connected to the radio frequency module.

What is claimed is:

1. A radio frequency module comprising:
a substrate having a mounting surface;
a first component and a second component, the first component and the second component being disposed on the mounting surface;
a first acoustic wave filter disposed between the first component and the second component on the mounting surface; and
a first shield electrode provided on at least one side surface of the first acoustic wave filter,
wherein the first shield electrode has a portion extending in a direction intersecting with a virtual line connecting the first component and the second component.

2. The radio frequency module according to claim 1, further comprising:
a second acoustic wave filter disposed between the first component and the second component on the mounting surface, the second acoustic wave filter being disposed alongside the first acoustic wave filter; and
a second shield electrode provided on at least one side surface of the second acoustic wave filter,
wherein the second shield electrode has a portion extending in the direction intersecting with the virtual line connecting the first component and the second component.

3. The radio frequency module according to claim 1, further comprising:
an inductor disposed adjacent to the first acoustic wave filter on the mounting surface,
wherein the inductor is electrically connected to the first acoustic wave filter,
wherein the first acoustic wave filter has a first side surface facing the inductor and a second side surface not facing the inductor, and
wherein the first shield electrode is not provided on the first side surface but is provided on the second side surface.

4. The radio frequency module according to claim 1,
wherein the first component is a component configured to transmit a signal.

5. The radio frequency module according to claim 1, further comprising:
an upper surface electrode constituting an upper surface portion of the radio frequency module,
wherein the first shield electrode is electrically connected to the upper surface electrode.

6. The radio frequency module according to claim 1,
wherein the first acoustic wave filter has a lower surface connected to the mounting surface with a bump electrode interposed between the lower surface and the mounting surface,
wherein a ground electrode not electrically connected to a circuit inside the first acoustic wave filter is disposed on the lower surface of the first acoustic wave filter, and
wherein the first shield electrode is electrically connected to the ground electrode.

7. A communication apparatus comprising:
the radio frequency module according to claim 1; and
an external circuit connected to the radio frequency module.

8. The radio frequency module according to claim 1,
wherein a long bump electrode electrically connected to a circuit inside the first acoustic wave filter is disposed on a lower surface of the first acoustic wave filter, and
wherein the long bump electrode has a portion extending in a direction intersecting with the virtual line connecting the first component and the second component.

9. The radio frequency module according to claim 1,
wherein the first component is a component configured to transmit a signal with a first frequency, and
wherein the second component is a component configured to transmit or receive a signal with a second frequency different from the first frequency.

10. The radio frequency module according to claim 1, further comprising:
a third component disposed alongside the first acoustic wave filter;
a second shield electrode provided on at least one side surface of the third component,
wherein the second shield electrode has a portion extending in the direction intersecting with the virtual line connecting the first component and the second component.

11. The radio frequency module according to claim 10,
wherein the first acoustic wave filter and the third component are disposed to be stacked with each other.

12. The radio frequency module according to claim 11,
wherein the third component is an electronic component.

13. The radio frequency module according to claim 11,
wherein in plan view of the first acoustic wave filter and the third component in a direction normal to the substrate, the radio frequency module has a portion where one of the first acoustic wave filter and the third component does not overlap with a remaining one of the first acoustic wave filter and the third component.

14. The radio frequency module according to claim 1,
wherein the first acoustic wave filter has a lower surface connected to the mounting surface with a bump electrode interposed between the lower surface and the mounting surface,
wherein a ground electrode electrically connected to a circuit inside the first acoustic wave filter is disposed on the lower surface of the first acoustic wave filter, and
wherein the first shield electrode and the ground electrode are connected with a connection wiring line for grounding interposed between the first shield electrode and the ground electrode, the connection wiring line being exposed on the side surface of the first acoustic wave filter.

15. The radio frequency module according to claim 14,
wherein a signal electrode electrically connected to the circuit inside the first acoustic wave filter is disposed on the lower surface of the first acoustic wave filter, and
wherein the signal electrode is connected to a signal connection wiring line having an end portion exposed on a side surface different from the side surface in which the first shield electrode is provided.

16. A communication apparatus comprising:
the radio frequency module according to claim 8; and
an external circuit connected to the radio frequency module.

17. A communication apparatus comprising:
the radio frequency module according to claim 2; and
an external circuit connected to the radio frequency module.

18. A communication apparatus comprising:
the radio frequency module according to claim 3; and
an external circuit connected to the radio frequency module.

19. A communication apparatus comprising:
the radio frequency module according to claim 4; and
an external circuit connected to the radio frequency module.

20. A communication apparatus comprising:
the radio frequency module according to claim 5; and
an external circuit connected to the radio frequency module.
